(19) United States
(12) Patent Application Publication
(10) Pub. No.: US 2017/0328967 A1
(43) Pub. Date: Nov. 16, 2017

(54) METHOD AND MAGNETIC RESONANCE APPARATUS FOR PROVIDING APPLICATION INFORMATION FOR A MAGNETIC RESONANCE EXAMINATION OF A PATIENT

(71) Applicant: Siemens Healthcare GmbH, Erlangen (DE)

(72) Inventor: Miriam Keil, Erlangen (DE)

(73) Assignee: Siemens Healthcare GmbH, Erlangen (DE)

(21) Appl. No.: 15/591,489

(22) Filed: May 10, 2017

(30) Foreign Application Priority Data
May 10, 2016 (DE) 102016208018.0

(51) Int. Cl. G01R 33/30; G01R 33/54; G01R 33/28

(52) U.S. Cl. CPC G01R 33/307; G01R 33/288; G01R 33/543

(57) ABSTRACT

In a method for providing application information for a magnetic resonance examination of a patient using a magnetic resonance apparatus, position data are provided to a control computer of the apparatus from a mobile accessory unit, wherein the mobile accessory unit is arranged during the magnetic resonance examination at least partially around the patient's body region that is to be examined. The control computer generates application information as a function of the position data from the mobile accessory unit, and emits the application information to a user.

### BACKGROUND OF THE INVENTION

### Field of the Invention

The present invention concerns a method for providing application information for a magnetic resonance examination of a patient using a magnetic resonance apparatus.

### Description of the Prior Art

A problem with a magnetic resonance (MR) examination of regions of a patient's body, for example a magnetic resonance examination of the patient's extremities, is that these body regions are arranged and/or positioned at least partially in an edge region of a homogeneity volume of the magnetic field in the MR data acquisition scanner. Because of the anatomical position of the body regions to be examined, the magnetic resonance examination of these body regions cannot be performed in the isocenter of the magnetic field.

Because of the arrangement of the body region to be examined in the edge region and because of the poorer homogeneity conditions of the magnetic field at those edge regions, additional measures must be taken by the person conducting the examination in order to achieve image data with a high image quality. These measures can be, for example, adjusted shim programs and/or changed gradient pulses. Furthermore, it may be necessary to conduct a number of positioning localizer measurements in advance, in order to determine the position of the examination region. However, these additional measures are very time-consuming and in the case of inexperienced users may result in user errors.

### SUMMARY OF THE INVENTION

An object of the present invention is to provide a simple and fast workflow during examinations in edge regions of the homogeneity volume.

A method in accordance with the invention for providing application information for a magnetic resonance examination of a patient using a magnetic resonance apparatus includes providing position data for a mobile accessory unit, wherein the mobile accessory unit is arranged during the magnetic resonance examination at least partially around the patient's body region that is to be examined, creation of application information as a function of the position data for the mobile accessory unit, and emitting the application information to a user.

Position data for the mobile accessory unit as used herein means data that contain position information for the mobile accessory unit during the magnetic resonance examination. Preferably the mobile accessory unit is positioned and/or arranged on a patient support of the magnetic resonance scanner for this purpose. The provision of position data here means an acquisition of position data by operation of a position data acquisition unit and/or loading and/or retrieving previously stored position data from a memory. The acquisition unit can be a position acquisition sensor and/or a further position acquisition source or detector.

The mobile accessory unit is preferably removably arranged on the patient support and/or is removably arranged on the patient. However, for the active magnetic resonance examination the mobile accessory unit preferably has a fixed position in relation to the patient and/or the patient support device. The mobile accessory unit is at least partially arranged around the patient's body region that is to be examined. The mobile accessory unit can also have a receiving part and/or a positioning part for receiving and/or supporting the patient's body region that is to be examined. The mobile accessory unit can be, for example, a local magnetic resonance coil device.

The application information is preferably generated by a control unit and/or a computer of the magnetic resonance apparatus. Furthermore the application information can be generated automatically and/or autonomously by the control unit and/or the computer. The application information can selectively include information to assist the user during the active magnetic resonance examination. The application information can include safety information, such as incorrect positionings, and/or adjusted measurement programs and/or adjusted measurement protocols. Furthermore the application information can include further information that appears expedient to those skilled in the art.

The application information is preferably emitted to the user via an output interface and/or a display unit of the magnetic resonance apparatus. The output interface and/or the display unit can be a screen and/or a monitor and/or a touch display, etc.

With the invention it is possible to provide the user with advantageous assistance. The assistance is achieved because of the known and/or acquired position data for the mobile accessory unit, such as a local magnetic resonance coil device. Even when the mobile accessory unit is arranged and/or positioned in an edge region of a homogeneity volume of the MR scanner, measures needed for the subsequent magnetic resonance examination can be carried out automatically and/or autonomously by the control unit and/or the computer on the basis of the position information provided for the mobile accessory unit. These measures can be, for example, an adjustment of measurement parameters and/or measurement protocols. These measures can be provided to the user by the application information. This enables even inexperienced users and/or users with only limited experience in the field of magnetic resonance imaging to perform magnetic resonance examinations simply and quickly. Furthermore, with the invention a particularly time-saving magnetic resonance examination can be accomplished, since a manual adjustment of measurement protocols to the position information can advantageously be omitted.

In an embodiment of the invention, the mobile accessory unit is a local magnetic resonance coil device. The local magnetic resonance coil device preferably is a shoulder coil or a foot coil or a hand coil and/or further local magnetic resonance coil devices appearing expedient to those skilled in the art. Such coil devices are designed and/or are suitable for an examination of the patient's body regions that are arranged in an edge region of the homogeneity volume of the scanner and/or partially outside the homogeneity volume of the scanner. This means that the patient's body region that is to be examined can particularly simply be located quickly and precisely on the basis of the position information for the mobile accessory unit.

In another embodiment of the invention, the mobile accessory unit is an intervention unit. The intervention unit can be, for example, a catheter for an intervention and/or further intervention units appearing expedient to those person skilled in the art. These can be fitted with a corresponding sensor for determining the position of the intervention unit. This makes simple and precise position information possible for a duration of an intervention, so that it is possible advantageously to dispense with additional position localizes measurements for determining the position of the intervention unit. Furthermore, a continuous adjustment of measurement protocols to the position of the intervention unit can be achieved.

If the mobile accessory unit is arranged at least partially in an edge region of a homogeneity volume of the magnetic resonance scanner, assistance can likewise advantageously be provided to the user in the case of examinations that require a great deal of effort to adjust measurement programs and/or measurement protocols. This enables a simple and quick operational sequence in the case of such magnetic resonance examinations. In this context, the homogeneity volume means the volume within a central region of the patient receiving region of the magnetic resonance scanner. The isocenter of the scanner is situated within the homogeneity volume, and the homogeneity volume defines a region that has a field strength of the basic magnetic field that is as uniform and constant as possible.

If the mobile accessory unit is arranged at least partially outside the homogeneity volume of the magnetic resonance device, assistance can likewise be provided to the user in the case of examinations that require a great deal of effort to adjust measurement programs and/or measurement protocols. Here as well, this enables a simple and quick operational sequence in the case of such magnetic resonance examinations.

In a further embodiment of the invention, the application information includes safety information, as a result of which safety for the patient and/or safety during the magnetic resonance examination can be increased. In particular, the user can be alerted by the safety information to an existing safety risk.

Particularly advantageously the safety information can be information about an incorrect positioning of the mobile accessory unit. Furthermore other safety information that appears expedient to those skilled in the art is readily conceivable. This enables the number of manual application errors during a magnetic resonance examination on a patient to be reduced, since the user can be made aware of an incorrect positioning directly during the positioning and/or support of the patient and/or of the mobile accessory unit.

In another embodiment of the invention, the application information includes a measurement program and/or measurement protocol for the magnetic resonance examination which is adjusted to the position of the mobile accessory unit. This advantageously enables the user to be provided with an automatically adjusted measurement program and/or an automatically adjusted measurement protocol, so that a time-consuming manual adjustment can be omitted. In particular a time-saving and simplified workflow and/or operational sequence can as a result be provided for the user. Furthermore, due to the adjustment of the measurement programs and/or of the measurement protocols an optimized image quality can be achieved and thus a measurement time can also be curtailed. Moreover, by adjusting the individual measurement programs and/or the individual measurement protocols only a few preconfigured measurement programs and/or measurement protocols need be made available, so that additional storage space can be saved. Preferably the adjustment of the measurement program and/or of the measurement protocol can take place automatically with respect to the position of the mobile accessory unit by the control unit and/or the computer.

In a further embodiment of the invention, the application information includes position information for a measurement center and the measurement center is a central region of the mobile accessory unit. By fixing the measurement center on the central region of the mobile accessory unit, time-consuming localizer scans to determine position information for the measurement center can advantageously be omitted. This enables a saving in measurement time during the examination on the patient. Preferably in this case the mobile accessory unit is arranged and/or positioned around the patient's body region that is to be examined. The measurement center preferably is a central region for the active magnetic resonance examination. Preferably an examination volume and/or an examination region of the magnetic resonance device is fixed on the basis of the measurement center.

Furthermore the invention encompasses a magnetic resonance apparatus that has a control computer and a mobile accessory unit and that is designed to execute a method for providing application information for a magnetic resonance examination of a patient. The control computer configured to provide position data for the mobile accessory unit, and the mobile accessory unit is arranged during the magnetic resonance examination at least partially around the patient's body region that is to be examined. The control computer is configured to generate application information as a function of the position data for the mobile accessory unit. The control computer is in communication with a display unit at which the application information is shown to a user.

It is thereby possible to provide the user with advantageous assistance. The assistance is achieved because of the known and/or acquired position data for the mobile accessory unit, such as a local magnetic resonance coil device for example. Even when the mobile accessory unit is arranged and/or positioned in an edge region of a homogeneity volume of a magnet unit, measures needed for the subsequent magnetic resonance examination can be carried out automatically and/or autonomously by the control computer on the basis of the position information provided for the mobile accessory unit, for example an adjustment of measurement parameters and/or measurement protocols, and these can be provided to the user by means of the application information. This enables even inexperienced users and/or users with only limited experience in the field of magnetic resonance imaging to perform magnetic resonance examinations simply and quickly. Furthermore, thanks to the invention a particularly time-saving magnetic resonance examination can be provided, since a manual adjustment of for example measurement protocols to the position information can advantageously be omitted.

The advantages of the magnetic resonance apparatus essentially correspond to the advantages of the inventive method for providing application information for a magnetic resonance examination on a patient, which were explained above in detail.

The present invention also encompasses a non-transitory, computer-readable data storage medium that is encoded with programming instructions. When the storage medium is loaded into the control computer of a magnetic resonance apparatus, the programming instructions cause the method according to the invention, as described above, to be implemented when the programming instructions are executed. The program code can be a source code, which must still be compiled and linked or which must only be interpreted, or an executable software code which, for execution, must only be loaded into a corresponding computer.

### BRIEF DESCRIPTION OF THE DRAWINGS

FIG. 1 shows an inventive magnetic resonance apparatus having a mobile accessory unit, in a schematic representation.

FIG. 2 illustrates positioning of the mobile accessory unit in an edge region of a homogeneity volume of the magnetic resonance scanner.

FIG. 3 shows the basic steps of the inventive method for providing application information for a magnetic resonance examination of a patient.

### DESCRIPTION OF THE PREFERRED EMBODIMENTS

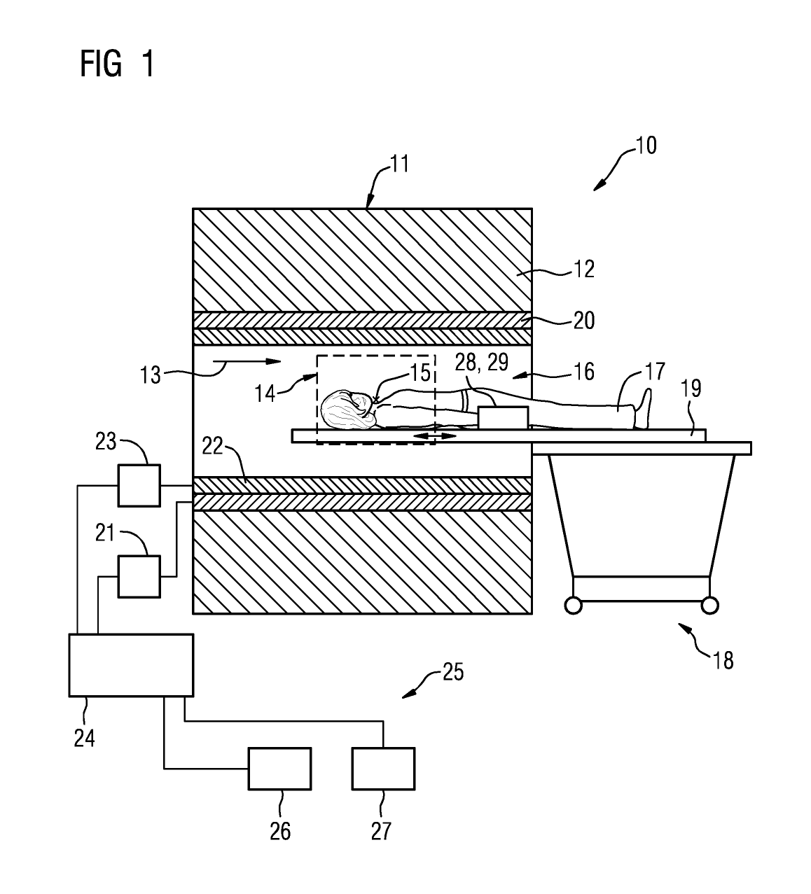

FIG. 1 shows schematically a magnetic resonance apparatus 10. The magnetic resonance apparatus 10 has a scanner 11 that has a superconducting basic field magnet 12 for generating a strong and constant basic magnetic field 13. A central region of the basic magnetic field 13 constitutes a homogeneity volume 14, which includes the isocenter 15 of the scanner 11.

The scanner 11 has a patient receiving region 16 to receive a patient 17. In the present exemplary embodiment, the patient receiving region 16 is configured to be cylindrical and is surrounded cylindrically in a peripheral direction by the scanner 11. In principle, however, a configuration of the patient receiving region 16 deviating therefrom is readily conceivable. The homogeneity volume 14 of the basic magnetic field 13 is situated within the patient receiving region 16.

The patient 17 can be moved by a patient support 18 into the patient receiving region 16. For this purpose, the patient support 18 has a patient bed or platform 19, which is configured to be movable within the patient receiving region 16.

The scanner 11 also has a gradient coil arrangement 20 for generating magnetic field gradients that are used for spatial encoding during imaging. The gradient coil arrangement 20 is controlled by a gradient controller 21. The scanner 11 furthermore has a radio-frequency antenna is controlled by a radio-frequency antenna controller 23 so as to radiate radio-frequency magnetic resonance sequences into an examination space that is substantially formed by a patient receiving region 16 of the scanner 11. The radiated radio-frequency magnetic resonance sequences give nuclear spins of certain atoms in the patient 17 a magnetization that causes those nuclear spins to be deflected from the basic magnetic field 13. As those nuclear spins relax and return to the steady state, they emit magnetic resonance signals, which are detected by the same, or a different, radio-frequency antenna from which the excitation signals were radiated.

For controlling the basic field magnet 12, the gradient controller 21 and for controlling the radio-frequency antenna controller 23, the magnetic resonance apparatus 10 has a control computer 24. The control computer 24 centrally controls the magnetic resonance apparatus 10, such as for the performance of a predetermined imaging gradient echo sequence. Furthermore, the control computer 24 has an evaluation processor (not shown) for evaluating medical image data that are acquired during the magnetic resonance examination. Furthermore, the magnetic resonance apparatus 10 has a user interface 25, which is connected to the control computer 24. Control information such as imaging parameters, as well as reconstructed magnetic resonance images, can be displayed to medical personnel on a display unit 26, for example on at least one monitor, of the user interface 25. In addition, the user interface 25 has an input unit 27 via which information and/or parameters can be entered by the medical personnel during a scanning procedure.

Furthermore the magnetic resonance apparatus 10 has a mobile accessory unit 28, which in the present exemplary embodiment is formed by a local magnetic resonance coil device 29. The local magnetic resonance coil device 29 is here formed as a local hand coil. In principle the design of the local magnetic resonance coil device 29 is not restricted to a local hand coil. Instead the local magnetic resonance coil device 29 can be formed by further local magnetic resonance coil devices 29, such as a local foot coil, a local shoulder coil, etc.

FIG. 3 schematically shows a method for providing application information for a magnetic resonance examination on the patient 17. The method is executed automatically and/or autonomously by the control computer 24, wherein for this purpose the control computer 24 has computer programs and/or software which are stored in a memory (not described in detail) of the control computer 24 and are executed by a processor unit (not described in detail) of the control computer 24 for the execution of the inventive method for providing application information for a magnetic resonance examination of the patient 17.

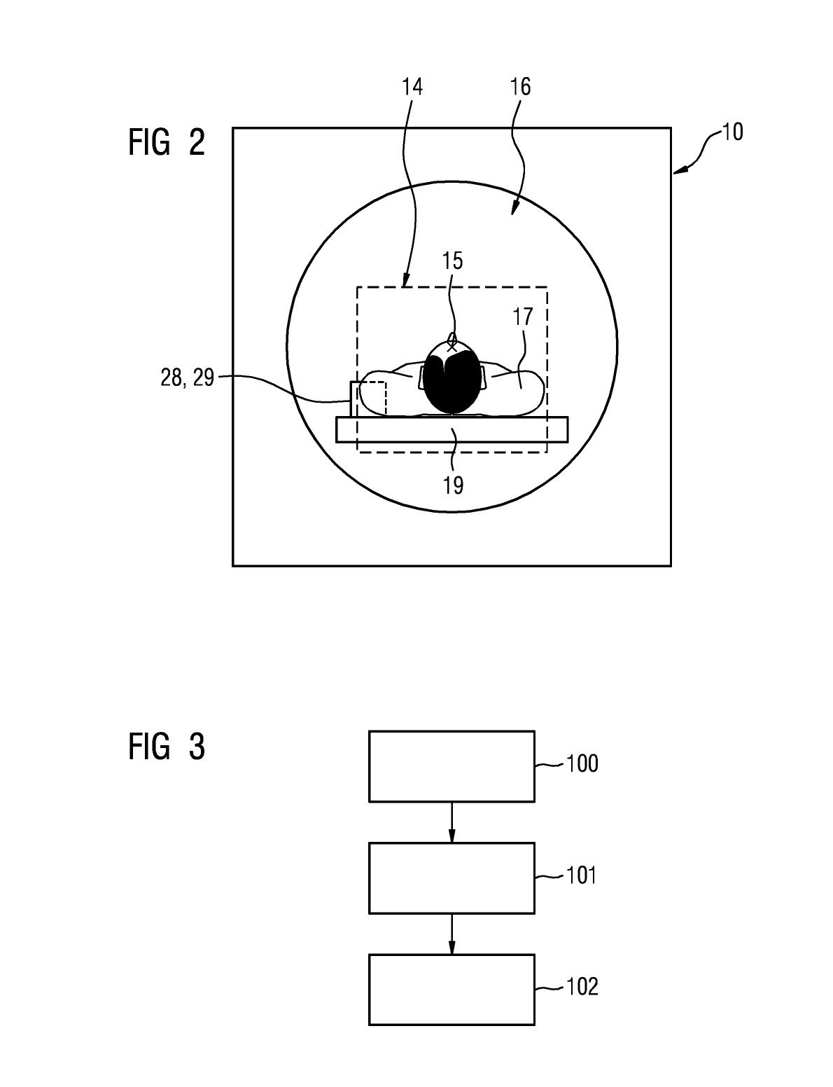

For the magnetic resonance examination of the body region to be examined, in the present case a hand, of the patient 17 the local magnetic resonance coil device 29, in particular the local hand coil, is arranged around the body region to be examined, in particular the hand, of the patient 17. The patient 17 and the local magnetic resonance coil device 29, in particular the local hand coil device, are here arranged and/or positioned on the patient bed 19 of the patient support device 18 (FIG. 2).

Because of an anatomical position of the body region to be examined, in particular the hand, of the patient 17 the body region to be examined, in particular the hand, is arranged on a lateral edge of the patient couch 19 when the patient 17 is in a lying position. As a consequence, the body region to be examined, in particular the hand, of the patient 17 is arranged in an edge region of the homogeneity volume 14 of the scanner 11 and/or also at least partially outside the homogeneity volume 14 of the scanner 11 (FIG. 2).

In a first method step 100, position data for the mobile accessory unit 28 are provided. The position data for the mobile accessory unit 28, in particular the local hand coil, is provided by the control computer 24. In this case the provision can involve a retrieval and/or loading of previously stored position data. Alternatively the provision can be the acquisition of current position data, wherein for this purpose the magnetic resonance apparatus 10 additionally has a position data acquisition unit, such as a position acquisition sensor, for example.

In principle the provision of position data is known to those skilled in the art from DE 10 2016 203 255, so that a detailed description of the provision of the position data is dispensed with at this point.

In a further method step 101 application information is generated on the basis of the position data provided. The application information is generated automatically by means of the control computer 24.

The application information can be safety information, such as in particular an incorrect positioning of the mobile accessory unit 28. For example, the safety information can be an alarm message, if the local magnetic resonance coil device 29, in particular the local hand coil device, directly abuts a housing surrounding the patient receiving region 16. Furthermore the safety information can be an alarm message if the local magnetic resonance coil device 29, in particular the local hand coil, is removed too far from the isocenter 15 of the basic field magnet 12, as can occur in the case of off-center measurements, and/or the safety information comprises an alarm message if the local magnetic resonance coil device 29 experiences an excessively strong curvature during the positioning.

Furthermore in the further method step 101 the application information can comprise a measurement protocol and/or measurement program for the magnetic resonance examination which are adjusted to the position of the mobile accessory unit 28, in particular the local magnetic resonance coil device 29. The measurement program and/or the measurement protocol are here adjusted automatically and/or autonomously by means of the control computer 24. Measurement parameters can here be adjusted by the control computer 24 to the position of the local magnetic resonance coil device 29, in particular to the position of the local hand coil, which is arranged at least partially in an edge region of the homogeneity volume 14 of the basic field magnet 12. For example, special gradient pulses can be provided, which take account of the position of the local magnetic resonance coil device 29 and generate only a few eddy currents. Furthermore special shim programs can be provided, which during positioning of the local magnetic resonance coil device 29, in particular the local hand coil device, are used at a large distance from the isocenter 15 of the basic field magnet 12.

Furthermore the application information can include position information for a measurement center, wherein the measurement center can be a central region of the mobile accessory unit 28. In this case the position information for the mobile accessory unit 28 can be used directly to locate and/or position the measurement center, such that additional localizer scans can be advantageously omitted and a time-saving magnetic resonance examination can be performed.

In a further method step 102 the application information is shown as an output to the user. Preferably the output is controlled by the control computer 24 by means of the display unit 26.

Alternatively or additionally the mobile accessory unit 28 can be an intervention unit. The intervention unit can be, for example, a catheter for an intervention and/or further intervention units appearing expedient to those skilled in the art. The position information from the intervention unit can here be incorporated, similarly to the above description, into the determination of the application information and can be employed for an adjustment of measurement programs. Furthermore, in the method step 101 application information containing safety information can be generated as a function of the position information from the intervention unit, for example in the case of an incorrect positioning of the intervention unit. Application information which contains position information for a measurement center can take place, similarly to the above description, in the method step 101, such that time-consuming localizer measurements for locating a position of the intervention unit can advantageously be dispensed with.

Although modifications and changes may be suggested by those skilled in the art, it is the intention of the Applicant to embody within the patent warranted hereon all changes and modifications as reasonably and properly come within the scope of the Applicant's contribution to the art.

1. A method for providing application information about a magnetic resonance (MR) examination of a patient, to be conducted in an MR data acquisition scanner of an MR apparatus, said MR data acquisition scanner having a patient-receiving opening therein, said method comprising:
placing a mobile accessory unit so as to extend at least partially around a body region of a patient to be examined using said MR data acquisition scanner;
from said mobile accessory unit that extends at least partially around said body region, providing a position data input to a computer that operates the MR data acquisition scanner, said position data input describing a position of said body region relative to said patient opening;
in said computer, using said position data input to generate at least one item of information associated with operation of said MR data acquisition scanner; and
making said at least one item of information available from the computer in electronic form to an operator of the MR data acquisition scanner.

2. A method as claimed in claim 1 wherein said mobile accessory unit is a component of a local MR coil of said MR data acquisition scanner.

3. A method as claimed in claim 1 wherein said examination involves use of an intervention instrument, and wherein said mobile accessory unit is incorporated in said interventional instrument.

4. A method as claimed in claim 1 wherein said patient opening has a homogeneity volume therein of said MR data acquisition scanner, and comprising placing said mobile accessory unit so as to extend at least partially around said body region in order to cause said mobile accessory unit to be placed at an edge region of said homogeneity volume.

5. A method as claimed in claim 1 wherein said patient opening has a homogeneity volume therein of said MR data acquisition scanner, and comprising placing said mobile accessory unit so as to extend at least partially around said body region in order to cause said mobile accessory unit to be placed at least partially outside of said homogeneity volume.

6. A method as claimed in claim 1 wherein said at least one item of information comprises safety information.

7. A method as claimed in claim 6 wherein said safety information identifies an incorrect positioning of said mobile accessory unit relative to said opening of said MR data acquisition scanner.

8. A method as claimed in claim 1 wherein said at least one item of information is selected from the group consisting of a measurement program that is adjusted dependent on the position of the mobile accessory unit relative to said opening, and a measurement protocol that is adjusted dependent on the position of the mobile accessory unit relative to said opening.

9. A method as claimed in claim 8 comprising, in said computer, automatically adjusting said measurement program or said measurement protocol dependent on the position of the mobile accessory unit relative to said opening.

10. A method as claimed in claim 1 wherein said at least one item of information comprises a designation of a measurement center for said examination, said measurement center being situated at a central region of said mobile accessory unit.

11. A magnetic resonance (MR) apparatus comprising:
an MR data acquisition scanner having a patient-receiving opening therein;
a computer configured to operate said MR data acquisition scanner;
a mobile accessory unit adapted to be placed on a patient in the MR data acquisition scanner so as to extend at least partially around a body region of the patient;
said mobile accessory unit that extends at least partially around said body region being configured to provide a position data input to said computer, said position data input describing a position of said body region relative to said patient opening;
said computer being configured to use said position data input to generate at least one item of information associated with operation of said MR data acquisition scanner; and
said computer being configured to make said at least one item of information available from the computer in electronic form to an operator of the MR data acquisition scanner.

12. A non-transitory, computer-readable data storage medium encoded with programming instructions, said storage medium being loaded into a control computer of a magnetic resonance (MR) apparatus comprising an MR data acquisition scanner having a patient opening therein, and a mobile accessory unit that extends at least partially around a body region of a patient to be examined using said MR data acquisition scanner, said programming instructions causing said computer to:
receive from said mobile accessory unit that extends at least partially around said body region, a position data input, said position data input describing a position of said body region relative to said patient opening;
use said position data input to generate at least one item of information associated with operation of said MR data acquisition scanner; and
make said at least one item of information available from the computer in electronic form to an operator of the MR data acquisition scanner.
